(19) United States
(12) Patent Application Publication
(10) Pub. No.: US 2025/0219584 A1
(43) Pub. Date: Jul. 3, 2025

(54) SIGNAL GENERATOR

(71) Applicant: Montage LZ Technologies (Chengdu) Co., Ltd., Sichuan (CN)

(72) Inventors: Lijiong Wang, Sichuan (CN); Jie Fan, Sichuan (CN); Xiaomin Si, Sichuan (CN); Qingxiang Dong, Sichuan (CN)

(73) Assignee: Montage LZ Technologies (Chengdu) Co., Ltd., Sichuan (CN)

(21) Appl. No.: 19/000,475

(22) Filed: Dec. 23, 2024

(30) Foreign Application Priority Data
Dec. 28, 2023 (CN) 202311852486.7

(51) Int. Cl. H03F 1/02; H04R 3/00

(52) U.S. Cl. CPC H03F 1/0233; H04R 3/00; H03F 2200/03

(57) ABSTRACT

A signal generator includes a signal output stage circuit, a sensor circuit, and a negative voltage generator circuit. The signal output stage circuit receives an operating voltage and a negative voltage as power supply voltages, and generates an output voltage to drive a load. The sensor circuit detects the load impedance and the operating voltage. The negative voltage generator circuit adjusts the driving capability of the negative voltage based on information related to the operating voltage and information related to the load impedance. The signal output stage circuit adjusts the driving capability of the output voltage based on information related to the load impedance.

### CROSS-REFERENCE TO RELATED APPLICATION

This application claims the priority benefit of China application serial no. 202311852486.7, filed on Dec. 28, 2023. The entirety of the above-mentioned patent application is hereby incorporated by reference herein and made a part of this specification.

### BACKGROUND

### Technical Field

The disclosure relates to a signal generator, particularly to a signal generator for an audio transceiver device.

### Description of Related Art

The audio output stage of an audio and video recording and playback conversion device (hereinafter referred to as “audio-video transceiver”) may be utilized for outputting processed audio signals. Due to the necessity of meeting the signal amplitude requirements stipulated in national standards, and the requirement for the amplitude to exceed the power supply voltage during chip operation, the audio output stage module typically incorporates discrete components such as cascaded amplifiers (which operates under high power supply voltage) on the printed circuit board to satisfy large swing requirements.

The prior art proposes the development of an integrated audio output stage in deep submicron process technology, without increasing the power supply voltage of the audio-video transceiver chip. It employs a negative voltage regulator, which generates a negative voltage to increase the upper limit of the output signal swing, thereby meeting the requirements of national standards.

However, the utilization of negative voltage in the development of integrated audio output stages employing these techniques may pose reliability risks. Furthermore, for varying loads, different standard requirements, and power supply variation, the inability to flexibly adjust the design parameters of relevant modules may risk compromising the performance of output signals. Moreover, in the presence of certain peripherals, the performance of output signals may deteriorate dramatically, potentially resulting in non-compliance with national standard requirements.

Moreover, as the market demand for low-cost, high-performance audio-video transceivers with audio output stages increases, there is a growing expectation for audio-video transceivers to employ integrated audio output stages capable of directly producing high-quality signals that comply with national standards. However, the utilization of integrated audio output stages that meet national standards and deliver high-quality signals has been significantly constrained, due to reliability risks associated with the introduction of negative voltage in the circuit as well as flexibility requirements under diverse different peripherals.

### SUMMARY

An objective of present disclosure is to provide a signal generator capable of dynamically adjusting the electrical characteristics of its output voltage based on the load impedance and the operating voltage.

According to embodiments of the present disclosure, the signal generator includes a signal output stage circuit, a sensor circuit, and a negative voltage generator circuit. The signal output stage circuit receives an operating voltage and a negative voltage as power supply voltages, and generates an output voltage to drive a load. The sensor circuit detects the load impedance and the operating voltage. The negative voltage generator circuit adjusts the driving capability of the negative voltage based on information related to the operating voltage and-the load impedance from the sensor circuit. The signal output stage circuit adjusts the driving capability of the output voltage based on the load impedance.

### BRIEF DESCRIPTION OF THE DRAWINGS

FIG. 1 is a schematic diagram of a signal generator according to an embodiment of the present disclosure.

FIG. 2 is a schematic diagram illustrating an implementation of the output stage circuit in an embodiment of the present disclosure.

FIG. 3 is a schematic diagram illustrating the implementation details of the negative voltage generator circuit in an embodiment of the present disclosure.

FIG. 4 is a schematic diagram illustrating an implementation of a charge pump circuit in an embodiment of the present disclosure.

FIG. 5 is a block diagram illustrating an implementation of a signal generator in another embodiment of the present disclosure.

FIG. 6 is a schematic diagram illustrating the adjustment action of the number of enabled charge pump circuits in the negative voltage generator circuit 520 in an embodiment of the present disclosure.

### DESCRIPTION OF THE EMBODIMENTS

Reference is now made in detail to exemplary embodiments of the present disclosure, examples of which are illustrated in the accompanying drawings. Where possible, the same reference numerals are used throughout the drawings and the description to refer to the same or like parts.

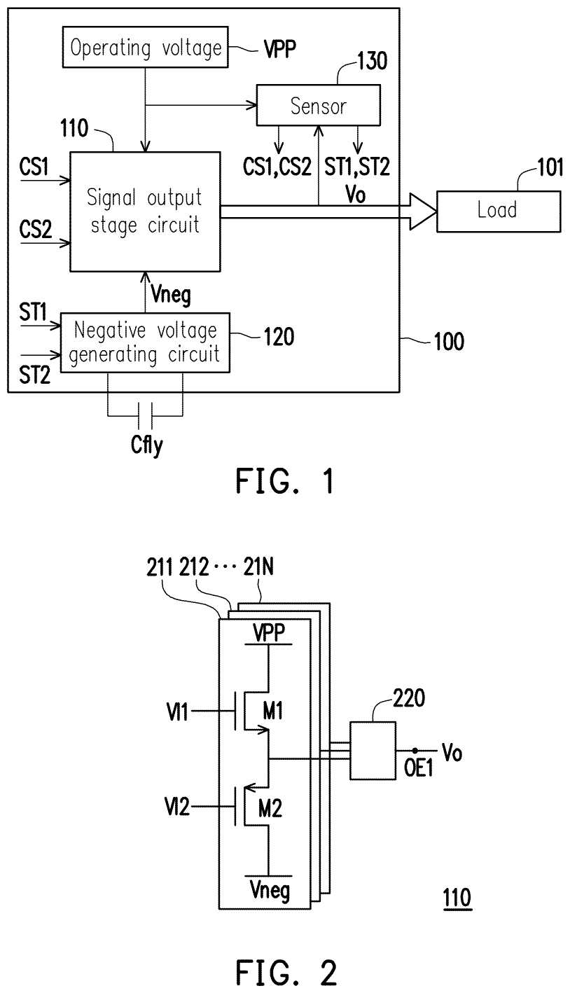

Please refer to FIG. 1, which illustrates a schematic diagram of a signal generator according to an embodiment of the present disclosure. The signal generator 100 includes a signal output stage circuit 110, a negative voltage generator circuit 120, and a sensor circuit 130. The signal generator 100 may constitute a part of an audio signal transceiver device. The signal output stage circuit 110 receives an operating voltage VPP and a negative voltage Vneg as power supply voltages. The output terminal of the signal output stage circuit 110 is coupled to a load 101. The signal output stage circuit 110 is configured to generate an output voltage Vo at its output terminal to drive the load 101. The negative voltage generator circuit 120 is coupled to the signal output stage circuit 110 and is configured to generate the negative voltage Vneg. The negative voltage generator circuit 120 is further coupled to a capacitor Cfly, wherein the capacitor Cfly is utilized to store charge and serve as a source of output current for the negative voltage Vneg. The output voltage Vo generated by the signal output stage circuit 110 may swing between the operating voltage VPP and the negative voltage Vneg.

The sensor circuit 130 is coupled to the operating voltage VPP and to the load 101. The sensor circuit 130 may be configured to detect the operating voltage VPP and to sense the impedance of the load 101, thereby obtaining information related to the operating voltage VPP and information related to the impedance of the load 101. Specifically, the sensor circuit 130 may include a voltage sensor for detecting the operating voltage VPP and a load sensor for sensing the impedance of the load 101. The load sensor may inject a test vector to the load 101, then obtain a feedback signal which may determine the information related to the impedance of the load 101. The aforementioned voltage sensor and load sensor may be implemented using voltage and load sensing circuits commonly known to those skilled in the art, without specific limitations.

On the other hand, the sensor circuit 130 may transmit the intensity signal ST1 of the detected operating voltage VPP and the intensity signal ST2 of the impedance of the load 101 to the negative voltage generator circuit 120. Furthermore, the sensor circuit 130 may generate control signals (control bits) CS1 and CS2 respectively based on the detected operating voltage VPP and the impedance of the load 101, and transmit the control signals CS1 and CS2 to the signal output stage circuit 110. In this embodiment of the present disclosure, the intensity signals ST1 and ST2 may be information in the same format as the control signals CS1 and CS2, respectively. Alternatively, in other embodiments of the present disclosure, the control signals CS1 and CS2 may be digital information of multiple bits, while the intensity signals ST1 and ST2 may be analog information.

Further elaborating, the signal output stage circuit 110 may adjust the driving capability of the output voltage Vo generated therein in accordance with the received control signals CS1 and CS2. The negative voltage generator circuit 120 may adjust the driving capability of the negative voltage Vneg generated therein based on the intensity signals ST1 and ST2.

Specifically, referring to FIG. 1 and FIG. 2, FIG. 2 is a schematic diagram of an implementation of the signal output stage circuit in an embodiment of the present disclosure. The signal output stage circuit 110 includes multiple signal output sub-circuits 211 to 21N. The multiple output terminals of the signal output sub-circuits 211 to 21N may be jointly coupled to the output terminal OE of the signal output stage circuit 110. In this embodiment, the multiple output terminals of the signal output sub-circuits 211 to 21N may be coupled to the output terminal OE of the signal output stage circuit 110 through a switch component 220. Specifically, the signal output stage circuit 110 may adjust the number of enabled signal output sub-circuits among the signal output sub-circuits 211 to 21N based on the load demand-related information provided by the sensor circuit 130. The switch component 220 may receive control signals CS1 and CS2, and obtain relevant information such as the operating voltage VPP and the impedance of load 101 through the control signals CS1 and CS2. The switch component 220 may determine the number of output terminals of the signal output sub-circuits 211 to 21N to be connected to the output terminal OE of the signal output stage circuit 110 based on the control signals CS2, thereby controlling the number of enabled signal output sub-circuits among the signal output sub-circuits 211 to 21N. It is worth noting that during normal operation, at least one of the signal output sub-circuits 211 to 21N is coupled to the output terminal OE of the signal output stage circuit 110; during standby, all signal output sub-circuits 211 to 21N are disconnected from the output terminal OE of the signal output stage circuit 110.

In an embodiment, each of the signal output sub-circuits 211 to 21N may possess an identical circuit architecture. Taking signal output sub-circuit 211 as an example, the signal output sub-circuit 211 may include a transistor M1 and a transistor M2. The first terminal of the transistor M1 receives an operating voltage VPP; the control terminal of the transistor M1 may receive an input voltage VI1; the second terminal of the transistor M1 is coupled to the first terminal of the transistor M2, serving to generate an output voltage Vo; the control terminal of the transistor M2 receives an input voltage VI2; and the second terminal of the transistor M2 receives a negative voltage Vneg. The transistor M1 may be a P-type transistor, while the transistor M2 may be an N-type transistor.

In addition, it should be noted that the transistors M1 and M2 may be any form of transistors without specific limitations. Furthermore, in this embodiment, the total quantity of the signal output sub-circuits 211 to 21N may be configured according to the actual requirements of the audio transceiver device, without any fixed restrictions.

It is noteworthy that, in the present embodiment, the number of enabled signal output sub-circuits 211 to 21N may be adjusted through the switch component 220. In other embodiments of the present disclosure, the switch component 220 may not be utilized; instead, the number of enabled signal output sub-circuits 211 to 21N may be determined based on the control signal CS2. In such cases, the signal output sub-circuits 211 to 21N that are not enabled are disabled and do not participate in the generation of the output voltage Vo.

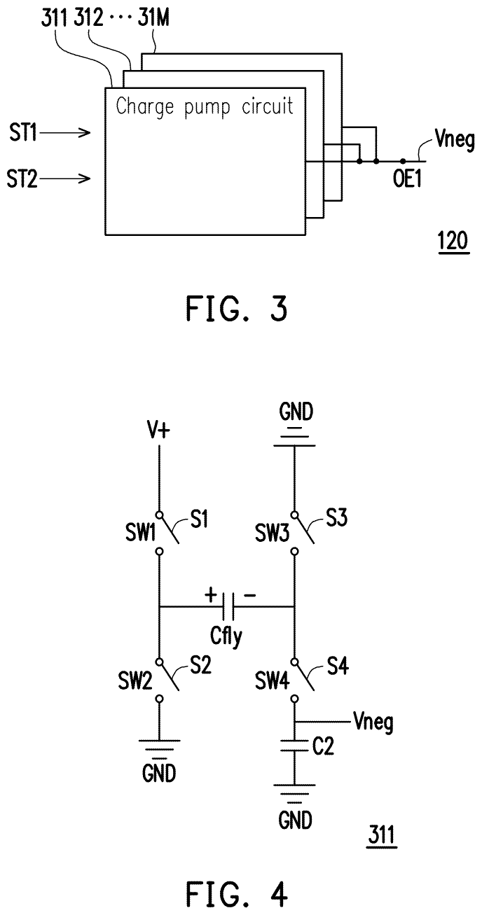

Please refer to FIG. 1 again. Regarding the implementation details of the negative voltage generator circuit 120, please refer to FIG. 3 and FIG. 1, wherein FIG. 3 is a schematic diagram illustrating the implementation details of the negative voltage generator circuit in an embodiment of the present disclosure. The negative voltage generator circuit 120 includes multiple charge pump circuits 311 to 31M. The multiple output terminals of the charge pump circuits 311 to 31M may be collectively coupled to the output terminal OE1 of the negative voltage generator circuit 120. The negative voltage generator circuit 120 receives the intensity signal ST1 of the operating voltage VPP and the intensity signal ST2 of the impedance of load 101, and determines the number of charge pump circuits 311 to 31M to be enabled based on the intensity signal ST1 and the intensity signal ST2.

Regarding the implementation details of the charge pump circuits 311 to 31M, reference may be made to FIG. 4, which illustrates an exemplary implementation of the charge pump circuit in an embodiment of the present disclosure. In FIG. 4, using THE charge pump circuit 311 as an example, the charge pump circuit 311 includes switches SW1 to SW4, as well as capacitors Cfly and C2. Specifically, the first terminal of the switch SW1 receives a base voltage V+; the second terminal of the switch SW1 is coupled to the first terminal of the capacitor Cfly; the first terminal of the switch SW2 is coupled to the first terminal of the capacitor Cfly; the second terminal of the switch SW2 receives a ground voltage GND; the first terminal of the switch SW3 receives the ground voltage GND; the second terminal of the switch SW3 is coupled to the second terminal of the capacitor Cfly; the first terminal of the switch SW4 is coupled to the second terminal of the capacitor Cfly; the second terminal of the switch SW4 is coupled to the first terminal of the capacitor C2. Furthermore, the first terminal of the capacitor C2 is utilized to generate a negative voltage Vneg, while the second terminal of the capacitor C2 receives the ground voltage GND.

In the initial state (such as the default state, upon power-up, or when entering standby mode), the switches SW1 to SW4 are all in an off state. During the discharge of the capacitor Cfly, the switches SW2 and SW3 may be simultaneously turned on according to control signals S2 and S3, respectively, while the switches SW1 and SW4 are turned off (off state) correspondingly according to control signals S1 and S4, respectively. At this time, the capacitor Cfly may undergo a discharge action, dissipating the internally stored charge. When generating negative voltage Vneg, in the first phase, the switches SW1 and SW3 may be turned on according to control signals S1 and S3, respectively (switches SW2 and SW4 are turned off), allowing the capacitor Cfly to charge. At this point, the voltage at the positive terminal of the capacitor Cfly may be to equal to the base voltage V+, while the voltage at the negative terminal of the capacitor Cfly is equal to the ground voltage GND. Subsequently, in the second phase, the switches SW2 and SW4 may be turned on according to the control signals S2 and S4, respectively (switches SW1 and SW3 are changed to be turned off). At this time, the positive terminal of the capacitor Cfly receives the ground voltage GND, and the negative terminal of the capacitor Cfly is connected to the first terminal of the capacitor C2. The capacitors Cfly and C2 may then engage in charge sharing, generating a negative voltage Vneg at the first terminal of the capacitor C2.

The aforementioned first and second phases may be executed repeatedly, enabling the accumulation and storage of charge in the capacitor C2. Consequently, the capacitor C2 may endow the negative voltage Vneg with sufficient driving capability.

Please be advised that, in the embodiment depicted in FIG. 3, multiple charge pump circuits 311 to 31M may share the same capacitor C2. Furthermore, multiple charge pump circuits 311 to 31M may share the same capacitor Cfly. In alternative embodiments of the present disclosure, multiple charge pump circuits 311 to 31M may not share the capacitor Cfly, and may instead each possess independent capacitors Cfly.

Please refer again to FIG. 1. Regarding the signal generator 100 in an embodiment of the present disclosure, the determination method for the number of enabled signal output sub-circuits and the number of enabled charge pump circuits may be explained as follows. The signal output stage circuit 110 may preset a first load impedance threshold. When it is determined that the load impedance is greater than the first load impedance threshold, the signal generator 100 is set to a heavy load state, and the number of enabled signal output sub-circuits is set to a first quantity. Furthermore, when the signal output stage circuit 110 determines that the load impedance is not greater than the first load impedance threshold, the signal generator 100 is set to a light load state. The signal output stage circuit 110 may set the number of enabled signal output sub-circuits to a second quantity, wherein the first quantity is greater than the second quantity.

The negative voltage generator circuit 120 may further establish a first voltage threshold. When the load impedance is greater than the aforementioned first load impedance threshold and the operating voltage VPP is greater than the first voltage threshold (high operating voltage), the negative voltage generator circuit 120 sets the number of the enabled charge pump circuits as a first quantity. When the load impedance is greater than the first load impedance threshold and the operating voltage VPP is not greater than the first voltage threshold (low operating voltage), the negative voltage generator circuit 120 sets the number of the enabled charge pump circuits as a second quantity. When the load impedance is not greater than the first load impedance threshold and the operating voltage VPP is greater than the first voltage threshold (high operating voltage), the negative voltage generator circuit 120 sets the number of the enabled charge pump circuits as a third quantity. When the load impedance is not greater than the first load impedance threshold and the operating voltage VPP is not greater than the first voltage threshold (low operating voltage), the negative voltage generator circuit 120 sets the number of the enabled charge pump circuits as a fourth quantity. The aforementioned second quantity>the aforementioned fourth quantity=the aforementioned first quantity>the aforementioned third quantity.

The above description may be summarized as follows in the table below.

| | High operating voltage | Low operating voltage |
|---|---|---|
| Heavy load | Relatively few signal output sub-circuits | |
| state | Relatively few | Standard quantity of |
| | charge pump circuits | charge pump circuits |
| Light load | Relatively larger number of signal output sub-circuits | |
| state | Standard quantity of | Relatively larger number of |
| | charge pump circuits | charge pump circuits |

Furthermore, in other embodiments of the present disclosure, the signal output stage circuit 110 may also pre-set multiple load impedance thresholds (e.g., a first load impedance threshold and a second load impedance threshold). When the load impedance is greater than the first load impedance threshold (heavy load state), the signal output stage circuit 110 sets the number of the multiple enabled signal output sub-circuits as the first quantity; when the load impedance is less than the second load impedance threshold (light load state), the signal output stage circuit 110 sets the number of the multiple enabled signal output sub-circuits as the second quantity; when the load impedance is between the first load impedance threshold and the second load impedance threshold (medium load state, also referred to as standard state), the signal output stage circuit 110 sets the number of the multiple enabled signal output sub-circuits as the third quantity, wherein the first load impedance threshold is greater than the second load impedance threshold, the first quantity is greater than the third quantity, and the third quantity may be greater than the second quantity.

Based on the above explanation, it can be understood that in the embodiments of the present disclosure, multiple load impedance thresholds and voltage thresholds may be set to determine the load impedance and the operating voltage. The driving capability of the output voltage Vo and the negative voltage Vneg generated by the signal output stage circuit 110 and the negative voltage generator circuit 120 may be adjusted in multiple stages based on the determined load impedance and the operating voltage, thereby improving the operational efficiency of the signal generator 100.

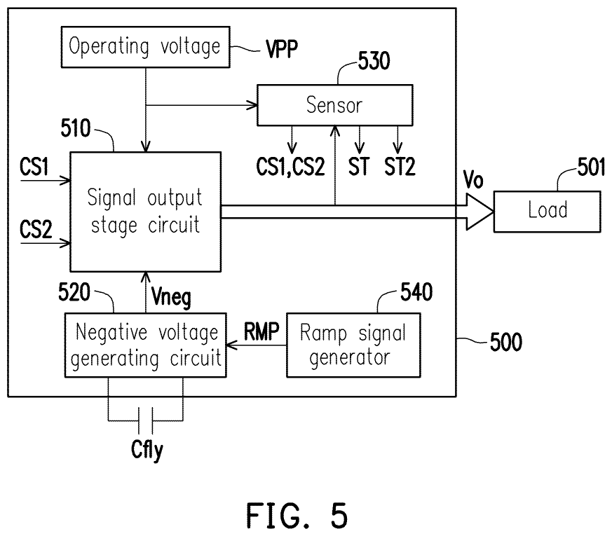

Please refer to FIG. 5, which illustrates a block diagram of an implementation of the signal generator in another embodiment of the present disclosure. The signal generator 500 includes a signal output stage circuit 510, a negative voltage generator circuit 520, a sensor circuit 530, and a ramp signal generator circuit 540. The signal generator 500 may be part of an audio transceiver device and is configured to generate an output voltage Vo to drive the load 501. The signal generator 500 is substantially similar to the signal generator 100 in the embodiment of FIG. 1, and the identical parts will not be elaborated upon herein. Differing from the aforementioned embodiment, the signal generator 500 additionally includes a ramp signal generator circuit 540. The ramp signal generator circuit 540 is coupled to the negative voltage generator circuit 520 and is configured to generate a ramp signal RMP. The ramp signal RMP may gradually increases (or decreases) according to a predetermined slope. When the negative voltage generator circuit 520 needs to adjust the number of charge pump circuits therein, the negative voltage generator circuit 520 may sequentially enable or disable each charge pump circuit based on the ramp signal RMP.)

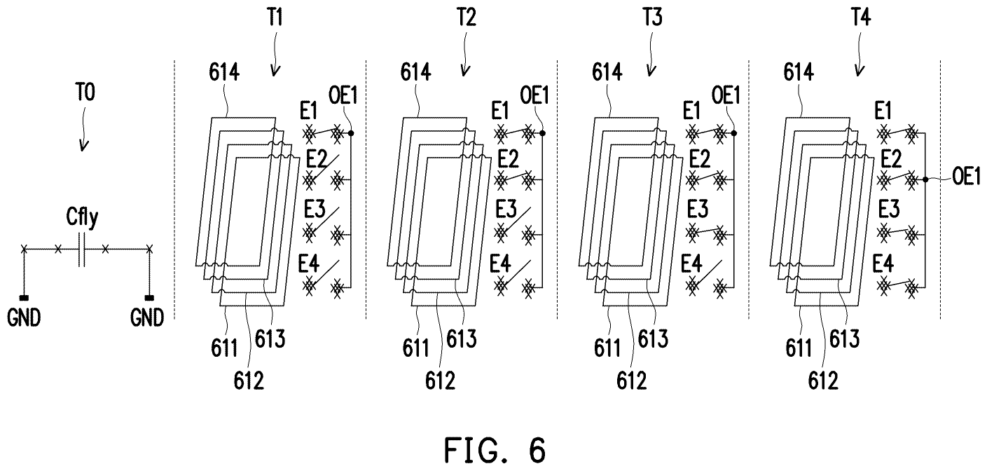

Please refer to FIG. 5 and FIG. 6 concurrently, wherein FIG. 6 illustrates the adjustment operation of the number of enabled charge pump circuits in the negative voltage generator circuit 520 in an embodiment of the present disclosure. In FIG. 6, the negative voltage generator circuit 520 includes four charge pump circuits 611 to 614. The charge pump circuits 611 to 614 respectively have four output terminals E1 to E4, while the negative voltage generator circuit 520 has an output terminal OE1. In the initial state (e.g., default state, power-on, or entering standby mode), all switches are in an off state. Upon entering state TO, the capacitor Cfly is discharged. That is, both terminals of the capacitor Cfly receive the ground voltage GND, thereby allowing the capacitor Cfly to be completely discharged. Subsequently, when the charge pump circuits 611 to 614 are to be enabled sequentially, the negative voltage generator circuit 520 may enter four states T1 to T4 in order, based on the rising state of the ramp signal RMP. In state T1, the negative voltage generator circuit 520 only couples the output terminal E1 of the charge pump circuit 611 to the output terminal OE1 of the negative voltage generator circuit 520, resulting in the number of enabled charge pump circuits 611 to 614 being 1. In state T2, the negative voltage generator circuit 520 couples the output terminals E1 and E2 of the charge pump circuits 611 and 612 to the output terminal OE1 of the negative voltage generator circuit 520, resulting in the number of enabled charge pump circuits 611 to 614 being 2. In state T3, the negative voltage generator circuit 520 couples the output terminals E1, E2, and E3 of the charge pump circuits 611, 612, and 613 to the output terminal OE1 of the negative voltage generator circuit 520, resulting in the number of enabled charge pump circuits 611 to 614 being 3. Finally, in state T4, the negative voltage generator circuit 520 couples the output terminals E1, E2, E3, and E4 of the charge pump circuits 611, 612, 613, and 614 to the output terminal OE1 of the negative voltage generator circuit 520, resulting in the number of enabled charge pump circuits 611 to 614 being 4.

Technical experts in this field understand that when a chip is exposed to atmospheric conditions, it is inevitable that charges will accumulate on the capacitors of the board due to various reasons. For instance, charges generated by static electricity may accumulate on the capacitor Cfly. When the capacitor Cfly initiates charging or discharging, these accumulated charges may potentially impact the internal components of the chip. Simultaneously, due to physical laws, the voltage across the capacitor Cfly cannot change instantaneously, resulting in a momentary high current at the onset of charging or discharging, which may also damage the internal components of the chip. Both the accumulated charge on the capacitor Cfly and the instantaneous high current during charging and discharging may influence the reliability of the chip. To address this issue, the present disclosure provides a method wherein, prior to the charging or discharging of the capacitor Cfly, the switches SW2 and SW3 are conducted while the switches SW1 and SW4 are turned off. This configuration isolates the capacitor Cfly from other circuit components and grounds two terminals of the capacitor Cfly, allowing for complete discharge of accumulated charges. Subsequently, by sequentially activating charge pump circuits 611 to 614, the method suppresses the occurrence of high instantaneous currents during charging and discharging. This approach effectively maintains the safety of circuit components during operation and mitigates potential electromagnetic interference.

Finally, it should be noted that: The aforementioned embodiments are provided solely to elucidate the technical solutions of the present disclosure and are not intended to be limiting thereof. Although the present disclosure has been described in detail with reference to the foregoing embodiments, it should be understood by those skilled in the art that: they may still modify the technical solutions described in the foregoing embodiments, or substitute equivalent alternatives for part or all of the technical features thereof; and such modifications or substitutions shall not cause the essence of the corresponding technical solutions to deviate from the scope of the technical solutions in the embodiments of the present disclosure.

What is claimed is:

1. A signal generator, comprising:
a signal output stage circuit, receiving an operating voltage and a negative voltage as power supply voltages, and generating an output voltage to drive a load;
a sensor circuit, detecting load impedance-of the load and the operating voltage; and
a negative voltage generator circuit, adjusting a driving capability of the negative voltage based on information related to the operating voltage and information related to the load impedance,
wherein the signal output stage circuit adjusts a driving capability of the output voltage based on the information related to the load impedance.

2. The signal generator according to claim 1, wherein the signal output stage circuit comprises a plurality of signal output sub-circuits, the signal output stage circuit adjusts a number of the plurality of enabled signal output sub-circuits based on the information related to the load impedance.

3. The signal generator according to claim 2, wherein when the load impedance is greater than a first load impedance threshold, the signal output stage circuit sets the number of the plurality of enabled signal output sub-circuits as a first quantity; when the load impedance is not greater than the first load impedance threshold, the signal output stage circuit sets the number of the plurality of enabled signal output sub-circuits as a second quantity, wherein the first quantity is greater than the second quantity.

4. The signal generator according to claim 2, wherein when the load impedance is greater than a first load impedance threshold, the signal output stage circuit sets the number of the plurality of enabled signal output sub-circuits as a first quantity; when the load impedance is less than a second load impedance threshold, the signal output stage circuit sets the number of the plurality of enabled signal output sub-circuits as a second quantity; when the load impedance is between the first load impedance threshold and the second load impedance threshold, the signal output stage circuit sets the number of the plurality of enabled signal output sub-circuits as a third quantity, wherein the first load impedance threshold is greater than the second load impedance threshold, the first quantity is greater than the third quantity, and the third quantity is greater than the second quantity.

5. The signal generator according to claim 2, wherein each of the plurality of signal output sub-circuits comprises:
a first transistor, wherein a first terminal of the first transistor receives the operating voltage, a control terminal of the first transistor receives a first input voltage, and a second terminal of the first transistor generates an output voltage; and
a second transistor, wherein a first terminal of the second transistor generates the output voltage, a control terminal of the second transistor receives a second input voltage, and a second terminal of the second transistor receives the negative voltage.

6. The signal generator according to claim 1, wherein the negative voltage generator circuit comprises a plurality of charge pump circuits, wherein output terminals of the plurality of charge pump circuits are coupled to each other, the negative voltage generator circuit adjusts the number of the plurality of enabled charge pump circuits based on the information related to the load impedance and the information related to the operating voltage.

7. The signal generator according to claim 6, wherein when the load impedance is greater than a first load impedance threshold and the operating voltage is greater than a first voltage threshold, the negative voltage generator circuit sets the number of the plurality of enabled charge pump circuits as a first quantity; when the load impedance is greater than the first load impedance threshold and the operating voltage is not greater than the first voltage threshold, the negative voltage generator circuit sets the number of the plurality of enabled charge pump circuits as a second quantity; when the load impedance is not greater than the first load impedance threshold and the operating voltage is greater than the first voltage threshold, the negative voltage generator circuit sets the number of the plurality of enabled charge pump circuits as a third quantity; when the load impedance is not greater than the first load impedance threshold and the operating voltage is not greater than the first voltage threshold, the negative voltage generator circuit sets the number of the plurality of enabled charge pump circuits as a fourth quantity,
wherein the second quantity>the fourth quantity=the first quantity>the third quantity.

8. The signal generator according to claim 6, wherein the negative voltage generator circuit enables the plurality of charge pump circuits in a time-division manner according to a ramp signal.

9. The signal generator according to claim 8, further comprising:
a ramp signal generator circuit, coupled to the negative voltage generator circuit, for generating the ramp signal.

10. The signal generator according to claim 6, wherein each of the charge pump circuits comprises:
a first capacitor;
a first switch, wherein a first terminal of the first switch receives a base voltage, and a second terminal of the first switch is coupled to a first terminal of the first capacitor;
a second switch, wherein a first terminal of the second switch is coupled to the first terminal of the first capacitor, and a second terminal of the second switch receives a ground voltage;
a third switch, wherein a first terminal of the third switch receives the ground voltage, and a second terminal of the third switch is coupled to a second terminal of the first capacitor;
a second capacitor, wherein a first terminal of the second capacitor is coupled to the second terminal of the first capacitor and generates the negative voltage, and a second terminal of the second capacitor receives the ground voltage; and
a fourth switch, wherein a first terminal of the fourth switch is coupled to the second terminal of the first capacitor, and a second terminal of the fourth switch is coupled to the first terminal of the second capacitor.

11. The signal generator according to claim 10, wherein the second switch and the third switch are simultaneously conducted, and the first capacitor is discharged.

12. The signal generator according to claim 11, wherein in a first phase, the first switch and the third switch are simultaneously conducted to charge the first capacitor; in a second phase, the second switch and the fourth switch are conducted to enable charge sharing between the first capacitor and the second capacitor, thereby generating the negative voltage at the first terminal of the second capacitor.

13. The signal generator according to claim 1, wherein the sensor circuit generates first control signal based on the load impedance, and generates second control signal according to the operating voltage, and the sensor circuit transmits the first control signal and the second control signal to the signal output stage circuit.
